(19) United States
(12) Patent Application Publication
(10) Pub. No.: US 2026/0133503 A1
(43) Pub. Date: May 14, 2026

(54) MASKLESS EXPOSURE SYSTEM HAVING IMAGE PROCESSING FUNCTION FOR SUBSTRATE POSITIONING

(71) Applicant: SDA CO., LTD, Gyeonggi-do (KR)

(72) Inventors: Sang Bum SHIM, Gyeonggi-do (KR); Chang Min IM, Gyeonggi-do (KR); Young Soung MOON, Gyeonggi-do (KR); Byeong Min LEE, Cheonan-si Chungcheongnam-do (KR)

(21) Appl. No.: 19/254,815

(22) Filed: Jun. 30, 2025

(30) Foreign Application Priority Data
Nov. 8, 2024 (KR) 10-2024-0157614
May 26, 2025 (KR) 10-2025-0068389

(51) Int. Cl. G03F 9/00; G02B 26/08; G03F 7/00; G06T 7/00; G06T 7/73

(52) U.S. Cl. CPC G03F 9/7092; G03F 7/70116; G03F 7/703; G03F 7/70508; G03F 7/70525; G03F 7/70533; G03F 7/70725; G03F 7/70775; G03F 9/7015; G03F 9/7084; G03F 9/7088; G06T 7/0004; G06T 7/73; G02B 26/0833; G06T 2207/30148; G06T 2207/30204

(57) ABSTRACT

A maskless exposure system having an image processing function for substrate positioning according to an embodiment is intended to provide precise position measurement and correction functions capable of detecting and correcting minute substrate alignment errors. Further, an objective of an embodiment is to provide a maskless exposure system having an image processing technology that automatically measures the substrate's roll, yaw, and pitch and reflects them in an exposure process.

### CROSS REFERENCE TO RELATED APPLICATION

The present application claims priority to Korean Patent Applications Nos. 10-2024-0157614 filed on Nov. 8, 2024, and 10-2025-0068389, filed on May 26, 2025, the entire contents of which are incorporated herein for all purposes by this reference.

### BACKGROUND

### Technical Field

A technical spirit of the present disclosure relates to a maskless exposure system having an image processing function for substrate positioning and, more specifically, to a system and method for correcting image data to be exposed through image processing on the basis of an image of a substrate.

### Description of the Related Art

Unless stated otherwise in this specification, the contents described in this section are not the related art about the claims of this application and not all of the contents included in this section are regarded as the related art.

In the semiconductor manufacturing processes of the related art, photolithography is commonly employed for patterning. This process includes an exposure process employing a mask to transfer a designed circuit pattern onto a wafer coated with photoresist. The exposure process enables formation of a desired circuit pattern by emitting a light source such as ultraviolet (UV) or extreme ultraviolet (EUV) onto a wafer through a mask.

A commonly used mask is formed by depositing an opaque film such as metallic chromium on a quartz substrate and etching it to form a circuit pattern consisting of a light-transmitting region and a light-blocking region. Thereafter, the mask is fixed on a stage and light is emitted onto a wafer after precise alignment.

However, in the mask exposure process of the related art, precise alignment is required to achieve high-resolution patterns, and slight errors or distortion of the mask occurring in this process can affect the overlay accuracy of the pattern and lower the yield. In addition, contamination or damage to masks may occur due to the repeated execution of the exposure process, which results in degraded pattern transfer quality.

In particular, in advanced fine processes, since precision on the order of several nanometers (nm) is required, there is a limitation that it is difficult to satisfy such requirements with mask-based exposure methods of the related art. Accordingly, development of technology that improves exposure precision and enhances resistance to mask contamination and damage is required.

In the mask exposure process of the related art, exposure is performed using a mask to form circuit patterns on a substrate, but there is a problem of high costs for mask fabrication and management and complex processes. To address this problem, maskless exposure systems have been introduced, but pattern alignment issues due to slight substrate position errors remain challenges to be solved. In particular, substrate errors including roll, yaw, and pitch can affect the precise position of patterns, and if these are not precisely measured and corrected, the quality of the exposed circuits may deteriorate. Accordingly, technology that performs high-precision exposure by automatically measuring and correcting substrate errors is needed.

### SUMMARY

A maskless exposure system having an image processing function for substrate positioning according to an embodiment is intended to provide precise position measurement and correction functions capable of detecting and correcting minute substrate alignment errors.

Further, an objective of an embodiment is to provide a maskless exposure system having an image processing technology that automatically measures the substrate's roll, yaw, and pitch and reflects them in an exposure process.

The objects of the present disclosure are not limited to those described above and other objects not stated herein may be clearly understood by those skilled in the art from the following description.

A maskless exposure system according to an embodiment includes: a management information processing device configured to transmit image data to be exposed to a controller via a high-speed communication and transmit various preset exposure-related parameters set to a trigger generator; the controller configured to convert the image data received from the management information processing device into an output image and transmit the output image to a DMD control unit; a stage on which a substrate to be exposed is mounted and configured to move in an direction opposite to an exposure direction and generate and transmit encoder to the trigger generator signals while moving; an image capturing unit configured to capture an image of the substrate and transmit the image to the management information processing device; a trigger generator device configured to accumulate the number of pulses of the encoder signals received from the stage, and generate and transmit a trigger signal to the DMD control unit each time the accumulated number of pulses of the encoder signals corresponding to a position to be exposed is reached; the DMD control unit configured to adjust angles of specific micromirrors of a DMD on the basis of the output image received from the controller trigger signals received from the trigger generator; a light source configured to emit exposure light; the DMD configured to reflect the light from the light source to expose a desired position on the substrate using specific micromirrors of which the angles are adjusted by the DMD control unit; and an optical system configured to refract the light reflected by the DMD to expose a desired position on the substrate to the light, wherein the management information processing device includes: an image processing unit configured to calculate roll (rotation), yaw (lateral deviation), and pitch (longitudinal tilt) errors of the substrate on the basis of the image received from the image capturing unit; and an image correcting unit configured to generate a corrected image by correcting the image to be exposed on the basis of the roll (rotation), yaw (lateral tilt), and of pitch (longitudinal tilt) errors the substrate calculated by the image processing unit.

Further, the image processing unit may extract reference markers or feature points on the substrate from the image, calculate position errors between actual positions of the extracted feature points and reference positions, calculate roll (rotation), yaw (lateral tilt), and pitch (longitudinal tilt) information of the substrate on the basis of the position errors, and correct the position of the substrate on the basis of the calculated roll, yaw, and pitch information.

Further, the image processing unit may correct the roll, yaw, and pitch of the substrate by correcting and controlling a position and an orientation of the stage supporting the substrate.

Further, the image processing unit may estimate orientation errors of the substrate using relative distances and angles between the reference markers through matrix transformation or the least squares method.

Further, the image processing unit may detect the reference markers after performing pre-processing, which includes at least one of filtering, binarization, edge detection, and corner detection, on the image.

Further, the reference positions may include a predefined alignment reference coordinate system based on a layout design of the substrate or a master coordinate system.

Further, the position errors may be determined on the basis of an average value or a weighted average value calculated from a plurality of reference markers on the substrate.

Further, the image processing unit may perform the position correction in a three-dimensional coordinate system when the substrate has a curved or irregular shape.

The maskless exposure system according to an embodiment enables high-resolution and high-precision patterning by detecting minute alignment errors of a substrate through an image processing function and correcting them in real time. Accordingly, the overlay accuracy in an exposure process is improved, whereby the overall process yield and productivity are improved.

Further, in an embodiment, attitude information such as roll, yaw, and pitch of a substrate is automatically measured and reflected in real time in the exposure process, whereby it is possible to minimize errors even in processes requiring precision on the order of several nanometers. This enables increasing exposure precision for substrates having complex three-dimensional structures or irregular shapes.

Further, in an embodiment, by using a maskless exposure method, mask manufacturing and management costs can be reduced, and rapid pattern changes are possible when products are changed, thereby improving production flexibility.

Further, in an embodiment, unlike existing manual or semi-automatic alignment methods, image processing-based automatic position correction minimizes operator intervention and enables a fully automated process flow, thereby significantly improving the efficiency and repeatability of the entire process.

The effects obtainable from the exemplary embodiments of the present disclosure are not limited to the effects described above, and other effects not mentioned may be clearly derived and understood by those skilled in the art to which the exemplary embodiments of the present disclosure pertain from the following description. That is, unintended effects resulting from the implementation of the exemplary embodiments of the present disclosure can also be derived by those skilled in the art from the exemplary embodiments of the present disclosure.

### BRIEF DESCRIPTION OF THE DRAWINGS

FIG. 1 is a block diagram of a maskless exposure system 100 according to an embodiment of the present disclosure;

FIG. 2 is a block diagram of a management information processing device 10 of the maskless exposure system 100 according to an embodiment of the present disclosure;

FIG. 3 is a diagram illustrating a process in which an image processing unit according to an embodiment of the present disclosure recognizes feature points on a substrate and calculates position and orientation errors (roll, yaw, and pitch); and

FIG. 4 is a diagram illustrating a substrate position correction process according to an embodiment.

### DETAILED DESCRIPTION

A maskless exposure system according to an embodiment includes: a management information processing device configured to transmit image data to be exposed to a controller via a high-speed communication and transmit various preset exposure-related parameters set to a trigger generator; the controller configured to convert the image data received from the management information processing device into an output image and transmit the output image to a DMD control unit; a stage on which a substrate to be exposed is mounted and configured to move in an direction opposite to an exposure direction and generate and transmit encoder to the trigger generator signals while moving; an image capturing unit configured to capture an image of the substrate and transmit the image to the management information processing device; a trigger generator device configured to accumulate the number of pulses of the encoder signals received from the stage, and generate and transmit a trigger signal to the DMD control unit each time the accumulated number of pulses of the encoder signals corresponding to a position to be exposed is reached; the DMD control unit configured to adjust angles of specific micromirrors of a DMD on the basis of the output image received from the controller and the trigger signals received from the trigger a generator; light source configured to emit exposure light; the DMD configured to reflect the light from the light source to expose a desired position on the substrate using specific micromirrors of which the angles are adjusted by the DMD control unit; and an optical system configured to refract the light reflected by the DMD to expose a desired position on the substrate to the light, wherein the management information processing device includes: an image processing unit configured to calculate roll (rotation), yaw (lateral deviation), and pitch (longitudinal tilt) errors of the substrate on the basis of the image received from the image capturing unit; and an image correcting unit configured to generate a corrected image by correcting the image to be exposed on the basis of the roll (rotation), yaw (lateral tilt), and pitch (longitudinal tilt) errors of the substrate calculated by the image processing unit.

Hereafter, various embodiments of the present disclosure are described with reference to accompanying drawings. Various embodiments of the present disclosure may include various modifications and multiple embodiments, so certain embodiments are illustrated in the drawings and described in detail. However, it is to be understood that various embodiments of the present disclosure are not limited to specific exemplary embodiments, but include all modifications and/or equivalents, and substitutions included in the spirit and the scope of an embodiment of the present disclosure. In the description of drawings, similar components are given similar reference numerals.

It should be understood that the terms “comprises” or “have” used in various embodiments of the present disclosure specify the presence of stated features, steps, operations, components, parts, or a combination thereof, but do not preclude the presence or addition of one or more other features, numerals, steps, operations, components, parts, or a combination thereof.

In various embodiments of the present disclosure, expressions such as “or” include any and all combinations of the listed terms. For example, “A or B” may include A, B, or both A and B.

Terms such as “first,” “second,” “primary,” or “secondary” used in various embodiments of the present disclosure may be used to describe various components of various embodiments, but do not limit the components. For example, such terms do not limit the order and/or importance of the components, and may be used to distinguish one component from another.

It should be understood that when one component is referred to as being “connected to” or “coupled to” another component, it may be connected directly to or coupled directly to another component, but another new component may exist therebetween.

In embodiments of the present disclosure, terms such as “module”, “unit”, and “part” are terms for indicting a component that performs at least one function or operation and the component may be implemented as hardware or software, or a combination of hardware and software. Further, a plurality of “modules”, “units”, and “parts” may be implemented as at least one processor by being integrated into at least one module or chip except for the case that they each need to be implemented as specific individual hardware.

It must be understood that the terms defined by the dictionary are identical with the meanings within the context of the related art, and they should not be ideally or excessively formally defined unless they are clearly defined in various embodiments of the present disclosure.

The present disclosure is described hereafter in detail with reference to the accompanying drawings.

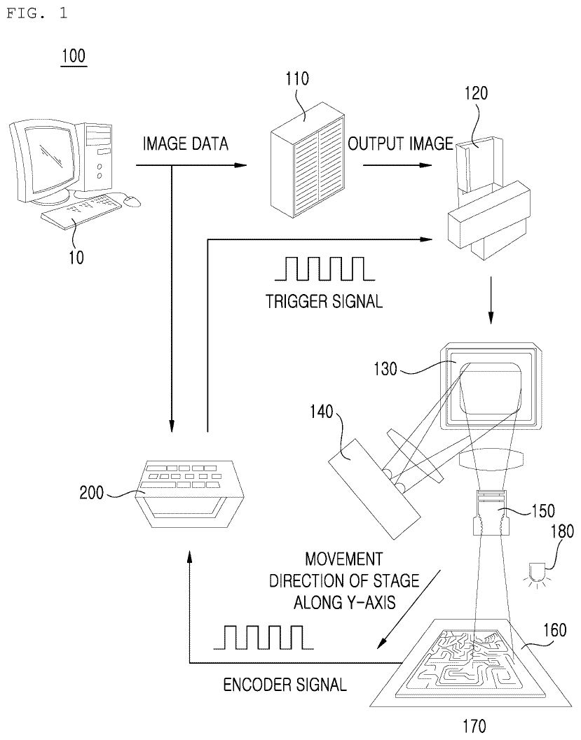

FIG. 1 is a block diagram of a maskless exposure system 100 according to an embodiment of the present disclosure. Referring to FIG. 1, the maskless exposure system 100 according to an embodiment of the present disclosure includes a management information processing device 10, a controller 110, a stage 170, an image capturing unit 180, a trigger generator 190, a Digital Micromirror Device (DMD) control unit 120, a light source 140, a DMD 130, and an optical system 150.

The management information processing device 10 transmits image data to be exposed to the controller 110 via a high-speed communication, and transmits various exposure-related parameters set by an operator to the trigger generator 200. The management information processing device 10 may be a type of computing device including at least one memory and at least one Central Processing Unit (CPU), or a combination thereof.

The controller 110 converts image data received from the management information processing device 10 into an output image and transmits the output image to the DMD control unit 120.

A substrate 160 to be exposed can be mounted on the stage 170, and the stage e 170 moves in the direction opposite to an exposure direction, and generates and transmits encoder signals to the trigger generator 190 while moving. The moving direction of the stage 170 is the y-axis direction, and typically, the stage 170 generates an encoder signal (pulse) every 0.1 μm of movement along the y-axis. That is, if the stage 170 moves 100 mm, it generates a total of 1,000,000 encoder signals. However, this is merely an example and the movement distance of the stage 170 that generates encoder signals may be set differently.

The image capturing unit 180 captures an image of the substrate 160 mounted on the stage 170 and transmits the image to the management information processing device 10. The image capturing unit 180 may be installed over the stage 170 and may be a type of camera capable of capturing images.

The trigger generator 190 accumulates the number of pulses of encoder signals received from the stage 170, and generates and transmits a trigger signal to the DMD control unit 120 when the accumulated number of pulses reaches the number corresponding to a target exposure position.

The DMD control unit 120 adjusts the angles of specific micromirrors of the DMD 130 on the basis of the output image received from the controller 110 and the trigger signal received from the trigger generator 190.

The DMD 130 is a device that displays images by controlling the reflection of light through fine mirrors of 16-micron size embedded on a silicon wafer at 1-micron intervals. This technology is based on a small microchip called a micro-device, which serves as a core component, and hundreds of thousands of microscopic aluminum mirrors are mounted on the microchip. These microscopic mirrors switch their positions in response to video signals, and when a light source shins light onto the surface of the aluminum mirrors, the mirrors collecting the light through a lens scan the video image, which is the basic principle of the DMD.

The light source 140 emits light for exposure, and an LED, a laser, etc. are commonly used. The angles of specific micromirrors of the DMD 130 are adjusted by the DMD control unit 120 so that the light from the light source 140 is reflected to expose a desired position on the substrate 160. The DMD is composed of multiple micromirrors arranged in an array.

The optical system 150 refracts the light reflected from the DMD 130 such that a desired position of the substrate is exposed.

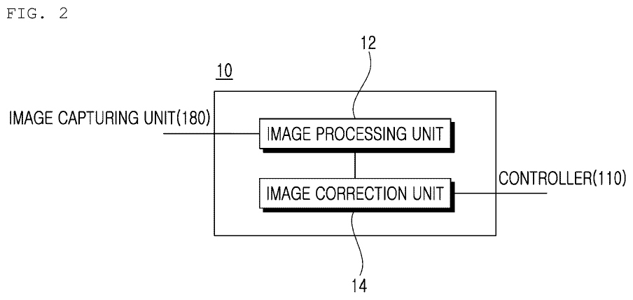

FIG. 2 is a block diagram of the management information processing device 10 of the maskless exposure system 100 according to an embodiment of the present disclosure. Referring to FIG. 2, the management information processing device 10 may include an image processing unit 12 and an image correction unit 14.

The image processing unit 12 can calculate roll (rotation), yaw (later deviation), and pitch (longitudinal tilt) errors of a substrate based on an image received from the image capturing unit 180 in consideration of the positions of the image capturing unit 180 and the substrate. A plurality of marks may be formed on a substrate, and roll (rotation), yaw (later deviation), and pitch (longitudinal tilt) errors of the substrate can be calculated by taking into account the distances between the plurality of marks.

The image correction unit 14 can generate a corrected image by correcting the image to be exposed on the basis of the roll (rotation), yaw (later deviation), and pitch (longitudinal tilt) errors of the substrate calculated by the image processing unit 12. Here, the corrected image may be a pre-distorted image that allows accurate exposure by taking into account the roll (rotation), yaw (later deviation), and pitch (longitudinal tilt) errors of a substrate.

In an embodiment, the image processing unit 12 extracts reference markers or feature points on the substrate from the image, calculates position errors between the actual positions of the extracted feature points and reference positions, calculates roll (rotation), yaw (later deviation), and pitch (longitudinal tilt) information of the substrate on the basis of the position errors, and corrects the position of the substrate on the basis of the calculated roll, yaw, and pitch information.

The image processing unit according to an embodiment processes the image of the substrate input from the imaging unit, extracts reference markers or feature points formed on the substrate, and calculates the actual position of the substrate on the basis of the image coordinates of the extracted feature points. Then, the image processing unit calculates the position errors of the substrate by calculating the difference between the actual position and a previously stored reference position. The position errors may include not only translational movement in the X-axis and Y-axis directions but also changes in orientation such roll (rotation), yaw (later deviation), and pitch (longitudinal tilt) of the substrate.

To this end, the image processing unit 12 analyzes the relative positions, angles, gaps, etc. between the plurality of feature points and quantitatively calculates orientation error information in three-dimensional space through matrix transformation or least squares method. The calculated roll, yaw, and pitch values are transmitted to a control unit or a correction algorithm module, and then the actual orientation of the substrate can be precisely corrected to match an alignment reference by controlling the stage or a position control device that supports the substrate.

With such a configuration, the maskless exposure system according to the present disclosure can improve overlay accuracy in a patterning process that requires high-precision alignment, and further, can realize automated alignment correction even for curved substrates or non-standard materials.

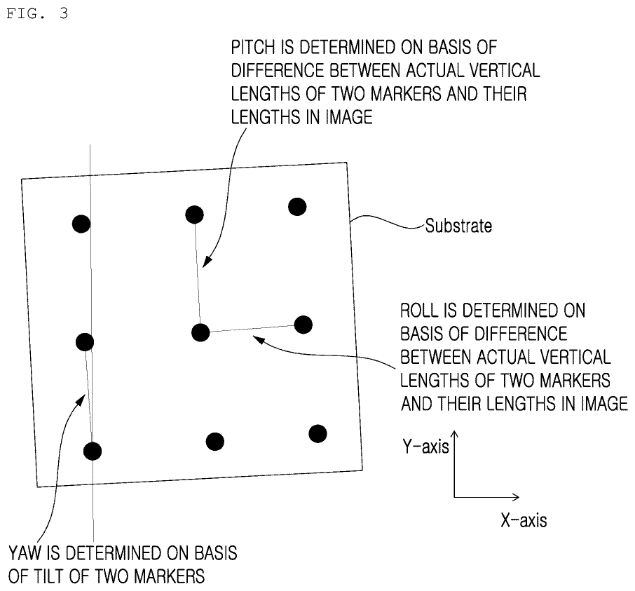

FIG. 3 is a diagram illustrating a process in which an image processing unit according to an embodiment of the present disclosure recognizes feature points on a substrate and calculates position and orientation errors (roll, yaw, and pitch). Referring to FIG. 3, the image processing unit 12 according to an embodiment of the present disclosure extracts reference markers or feature points (P1-P9) on a substrate 100 from an image input from the imaging capturing unit. The substrate 100 includes a plurality of reference markers arranged in a predetermined pattern, as shown in the figure, and the ideal position of each marker is defined in advance in accordance with a reference coordinate system (X and Y reference axes). However, in an actually captured image, due to the effects of rotation, tilt, positional movement, etc. of a substrate, the positions of feature points have deviations from reference positions. The image processing unit 12 performs the following procedures by detecting the coordinates of feature points (P1˜P9) in the image and comparing them with the reference coordinate system. In an embodiment, during a position error (translation error) calculation process, the amount by which the substrate's center deviates from the reference position is calculated as AX and AY. Then, orientation errors are calculated. In an embodiment, the position errors including rotation (roll), later deviation (yaw), and longitudinal (pitch) are calculated on the basis of the distances and angles between a plurality of feature points. For example, yaw and pitch errors can be quantified on the basis of the difference between the reference distance and the actual distance between reference markers shown in the figure, and the direction of tilt. Then, an alignment vector is generated and correction values are derived. In FIG. 3, the arrows connected to the feature points represent movement vectors from the reference positions to the actual positions, and by comprehensively analyzing these vectors, the overall alignment state of the substrate is mathematically modeled.

In the embodiment, when the calculated roll, yaw, and pitch information is transmitted to the controller, the orientation of the stage supporting the substrate is automatically corrected on the basis of the errors, which enables a high-precision exposure process. Accordingly, even minute errors of the substrate can be quantitatively grasped through precise position and orientation analysis using a plurality of reference markers, and the overlay accuracy and yield of the exposure process can be improved through automatic correction. In particular, it can be applied as a key technology to prevent error accumulation in maskless exposure systems.

Further, the image processing unit 12 corrects the roll, yaw, and pitch of the substrate by correcting and controlling the position and orientation of the stage supporting the substrate. The image processing unit 12 recognizes reference markers or feature points from the image of the substrate received from the imaging capturing unit, and calculates the position and orientation errors of the substrate on the basis of them. The calculated position errors include planar movement of the substrate (X, Y directions) as well as three-dimensional orientation errors such as rotation (roll), later deviation (yaw), and longitudinal tilt (pitch) of the substrate.

In this case, the image processing unit 12 corrects and controls the position and orientation of the stage (not shown) supporting the substrate using the error information so that the substrate is precisely aligned with the reference position and orientation.

More specifically, the image processing unit 12 calculates correction amounts corresponding to the roll, yaw, and pitch values, and transmits these correction amounts to the drive system of the stage (e.g., a multi-axis precision actuator or a tilt correction mechanism) so that the substrate's orientation can be precisely adjusted on the basis of six degrees of freedom (6-DOF).

This correction control process can be performed in real-time, whereby it is possible to effectively eliminate minute alignment errors of the substrate before the exposure or patterning process.

The image processing unit 12 estimates the orientation errors of a substrate using the relative distances and angles between reference markers through matrix transformation or the least squares method. The image processing unit 12 detects reference markers on the substrate from the image received from the imaging capturing unit and extracts the coordinates of the reference markers in the image. Then, the image processing unit 12 calculates the orientation errors of the substrate on the basis of the relative distance and angle information between the plurality of extracted reference markers. The orientation errors include rotation (roll), later deviation (yaw), and longitudinal tilt (pitch), and the image processing unit 12 applies mathematical modeling to estimate them quantitatively.

To this end, the image processing unit 12 constructs the relative position data between the reference markers in vector form, and estimates 3D orientation variation of the entire substrate by applying matrix transformation or the least squares method based on the difference from the ideal reference positions. For example, when reference markers are arranged in a square or grid pattern, the mapping relationship between the ideal and actual positions can be modeled as a 2D or 3D linear transformation matrix, and optimal roll, yaw, and pitch values can be calculated through error minimization based on the model. This method has the advantage of enabling robust correction against noise or incorrect recognition some of markers by estimating the overall orientation errors rather than local errors through averaging.

Hereafter, the process of mathematically modeling orientation errors (roll, pitch, and yaw) of a substrate using rotation matrices is described. Alignment errors of a substrate may include not only simple two-dimensional planar translation but also orientation changes (roll, pitch, and yaw) in three-dimensional space. In an embodiment of the present disclosure, such orientation errors are mathematically modeled on the basis of a rotation matrix to enable precise position and orientation correction. Rotational errors of a substrate can be expressed as individual rotation matrices with respect to three axes, as follows.

Yaw Rotation (Rotation about the Z-Axis)

The rotation matrix when a substrate rotates about a vertical axis (Z-axis) is given by Equation 1.

$${R}_{y} = [ \begin{matrix}cos {θ}_{y} & - sin {θ}_{y} & 0 \\ sin {θ}_{y} & cos {θ}_{y} & 0 \\ 0 & 0 & 1\end{matrix} ] \qquad Equation 1$$

Pitch Rotation (Rotation about the X-Axis)

The rotation matrix when a substrate tilts forward or backward about the X-axis, which is one of horizontal axes, is given by Equation 2.

$${R}_{p} = [ \begin{matrix}1 & 0 & 0 \\ 0 & cos {θ}_{p} & - sin {θ}_{p} \\ 0 & sin {θ}_{p} & cos {θ}_{p}\end{matrix} ] \qquad Equation 2$$

Roll Rotation (Rotation about the Y-Axis)

The rotation matrix when a substrate rotates left or right about the Y-axis (roll) is given by Equation 3.

$${R}_{r} = [ \begin{matrix}cos {θ}_{r} & 0 & sin {θ}_{r} \\ 0 & 1 & 0 \\ - sin {θ}_{r} & 0 & cos {θ}_{r}\end{matrix} ] \qquad Equation 3$$

The image processing unit 12 according to an embodiment estimates rotational amounts Oy, Op, and Or about the axes by analyzing the relative positions between reference markers on the substrate, and constructs a total rotation matrix R for overall orientation correction on the basis of the rotational amounts, as shown in Equation 4.

$$R = {R}_{y} {R}_{p} {R}_{r} \qquad Equation 4$$

The total rotation matrix R reflects orientation variation of a substrate in the actual three-dimensional space where it is placed, and the substrate can be precisely aligned with a reference coordinate system by correcting the orientation of the stage using the orientation variation.

Further, the image processing unit 12 detects reference markers after performing pre-processing, which includes at least one of filtering, binarization, edge detection, and corner detection, on an image. The image processing unit 12 according to an embodiment performs pre-processing for detecting reference markers or feature points on an on image of a substrate input from the image capturing unit.

The pre-processing is necessarily performed to improve the image quality and increase the accuracy of feature extraction, and specifically may include at least one or more procedures of filtering, binarization, edge detection, and corner detection. Filtering (filter processing) performs spatial filtering such as Gaussian filtering or median filtering for removing noise, thereby inducing image smoothing and improving detection accuracy. Binarization converts pixel values of an image into binary values and divides the pixels into black and white on the basis of a specific threshold, thereby clearly distinguishing reference markers from the background. This is particularly effective when markers have consistent contrast. Edge detection detects the contours (edges) of objects in an image and identifies the boundaries of markers using algorithms such as Sobel and Canny. This is advantageous for recognizing marker shapes such as a circle or a rectangle. Corner detection detects points where the corners or structural features of markers are prominent using algorithms such as Harris and Shi-Tomasi, thereby being able to precisely extract the positions of the markers.

The image processing unit 12, after performing the pre-processing process, detects the position of the reference markers from the preprocessed image, and calculates the errors with the reference positions, thereby being able to precisely analyze the position and orientation of the substrate.

In an embodiment, the reference positions include a predefined alignment reference coordinate system based on the layout design of a substrate or a master coordinate system. In an embodiment, the image processing unit 12 calculates position and orientation errors by calculating the actual positions of reference markers or feature points on a substrate and comparing them with the corresponding reference positions. In this case, the reference positions include a predefined alignment coordinate system based on the layout design file of the substrate or a master coordinate system. More specifically, the reference positions include ideal positions of the reference markers defined in the design information (e.g., CAD, GDS) used in the substrate manufacturing process or the exposure process, and these may be stored as either absolute or relative coordinates in accordance with the master coordinate system.

The image processing unit 12, by referring to the alignment coordinate system, calculates the differences (Δx, Δy, Δθ, etc.) between the actual positions of the markers recognized in real time and the reference positions, thereby being able to quantitatively analyze translation and orientation errors (roll, yaw, and pitch) of the substrate. In an embodiment, the error analysis method based on the reference coordinate system offers the advantage of ensuring consistency and reliability in repeated alignment processes because reference positions are clearly defined, and it can be flexibly applied to various substrate shapes and pattern structures.

Further, position errors are determined on the basis of the average value or weighted average value calculated from a plurality of reference markers on a substrate. The image processing unit 12 extracts individual position information from each of a plurality of reference markers or feature points arranged on the substrate, and calculates the position errors of the substrate on the basis of the differences between the actual positions and the reference positions of these markers.

In this case, the position errors are calculated on the basis of the average value or weighted average value of the error values calculated from the plurality of reference markers instead of using only the error value of a single marker.

More specifically, the representative position errors of the entire substrate can be quantified by integrating the position deviations (Δx, Δy) in the X and Y directions measured at reference markers using either an average or weighted average method. In this case, the weighted average values can be calculated by assigning different weights, depending on each marker's reliability, recognition quality, or position on the substrate, and can be expressed as Equation 5.

$$Δ {X}_{avg} = \frac{{\sum }_{i 1}^{n} {w}_{i} \cdot Δ {x}_{i}}{{\sum }_{i 1}^{n} {w}_{i}} , Δ {Y}_{avg} = \frac{{\sum }_{i 1}^{n} {w}_{i} \cdot Δ {y}_{i}}{{\sum }_{i 1}^{n} {w}_{i}} \qquad Equation 5$$

In Equation 5, wᵢ denotes the weight assigned to a reference marker i, and Δxᵢ and Δyᵢ represent position errors of corresponding markers. This method can minimize the influence caused by local measurement errors or noise and is advantageous in improving the alignment reliability of the entire substrate.

Further, when a substrate has a curved or irregular shape, the image processing unit 12 performs position correction in a three-dimensional coordinate system. In an embodiment, the image processing unit 12 recognizes a plurality of reference markers or feature points on a substrate and calculates position and orientation errors on the basis of the recognized reference marker or feature points. In particular, the image processing unit 12 is configured to perform a position correction operation in a 3D coordinate system so that precise alignment correction is possible even when a substrate has a curved surface or irregular shape rather than a flat surface.

More specifically, the image processing unit 12 converts the spatial coordinate information of feature points extracted from an image into a three-dimensional form, and analyzes the difference from ideal positions defined in the reference coordinate system, thereby quantitatively calculating position errors based on six degrees of freedom (6DOF), including translational movement in the X, Y, and Z axis directions as well as orientation errors such as roll, yaw, and pitch.

Thereafter, control commands for the stage or driving system that supports the substrate are generated on the basis of the calculated 3D position and orientation errors, and the position and orientation are automatically corrected such that the actual curved or irregular substrate is aligned with the reference coordinate system.

This method, unlike two-dimensional correction based on a flat substrate, has the advantage of enabling precise alignment even for complex shapes having Z-axis height variations or curvature, and can be effectively applied to the patterning process for flexible substrates, substrates for wearable devices, curved sensor substrates, or the like.

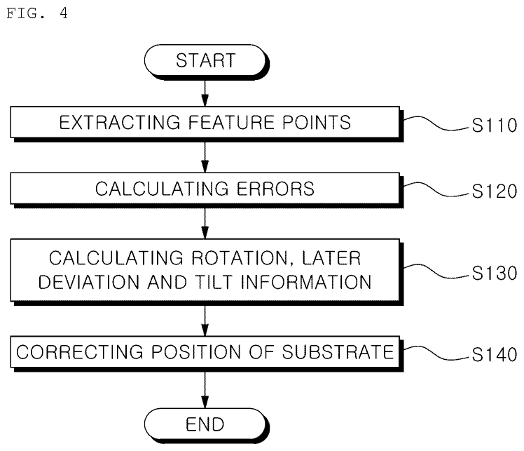

Hereafter, FIG. 4 will be described. The substrate position correction method shown in FIG. 4 may be performed by a maskless exposure system including the image processing unit 12.

Meanwhile, it should be noted that FIG. 4 is merely exemplary, and the present disclosure is not limited to that shown in FIG. 4. For example, steps may be arranged in a different order from that shown in FIG. 4, at least one of the steps shown in FIG. 4 may not be performed, or one or more steps not shown in FIG. 4 may be additionally performed.

Hereinafter, a substrate position correction method is described step by step. Since the operation (function) of the substrate position correction method according to an embodiment is essentially the same as the function of the substrate position correction system, redundant descriptions overlapping with FIGS. 1 to 3 will be omitted.

FIG. 4 is a diagram illustrating a substrate position correction process according to an embodiment. In step S110, reference markers or feature points on a substrate are extracted from an image, and in step S120, position errors between the actual positions of the extracted feature points and reference positions are calculated. In step S130, roll (rotation), yaw (later deviation), and pitch (longitudinal tilt) information of the substrate are calculated on the basis of the position errors. In step S140, the position of the substrate is corrected on the basis of the calculated roll, yaw, and pitch information.

The maskless exposure system according to an embodiment enables high-resolution and high-precision patterning by detecting minute alignment errors of a substrate through an image processing function and correcting them in real time. Accordingly, the overlay accuracy in an exposure process is improved, whereby the overall process yield and productivity are improved.

Further, in an embodiment, orientation information such as roll, yaw, and pitch of a substrate is automatically measured and reflected in real time in the exposure process, whereby it is possible to minimize errors even in processes requiring precision on the order of several nanometers. This enables increasing exposure precision for substrates having complex three-dimensional structures or irregular shapes.

Further, in an embodiment, by using a maskless exposure method, mask manufacturing and management costs can be reduced, and rapid pattern changes are possible when products are changed, thereby improving production flexibility.

Further, in an embodiment, unlike existing manual or semi-automatic alignment methods, image processing-based automatic position correction minimizes operator intervention and enables a fully automated process flow, thereby significantly improving the efficiency and repeatability of the entire process.

Meanwhile, the methods according to various embodiments of the present disclosure can be implemented in the form of an application or software program that can be installed on existing electronic devices.

In addition, the methods may be entirely or partially composed of multiple software function modules and may be implemented in an operating system (OS). Alternatively, each step may be configured as a single software function module, or multiple steps may be combined into a single software function module and implemented on an operating system. Therefore, even if all embodiments of the present disclosure are not implemented by a single software function module, if multiple software function modules implement respective steps of the present disclosure and are implemented within a single operating system, it can be understood that the method of the present disclosure is implemented.

Further, the methods according to various embodiments of the present disclosure may also be implemented through only a software upgrade or a hardware upgrade to existing electronic devices. Further, the various embodiments of the present disclosure described above may also be performed through an embedded server included in an electronic device or through external server of an electronic device.

Meanwhile, according to an embodiment of the present disclosure, the various embodiments described above may be implemented as software including instructions stored in a computer-readable recording medium that can be read by a computer or similar devices using software, hardware, or a combination thereof. In some cases, embodiments described in this specification may be implemented as a processor itself. According to software-based implementation, embodiments such as procedures and functions described in this specification may be implemented as specific software modules. Each of the software modules can perform one or more functions and operations described in this specification.

Meanwhile, the computer or similar devices may include a device that can call the stored instructions from a storage medium and operate according to the called instructions, and may include the device according to the disclosed embodiments. When the commands are executed by a processor, the processor can perform the functions corresponding to the commands directly or using other components that are controlled by the processor. The instructions may include codes that are created or executed by a compiler or an interpreter.

The recording medium readable by devices may be provided in the form of a non-transitory computer readable recording medium. The term ‘non-transitory’ means that a storage medium does not include a signal and is tangible and also it does not consider whether data is semi-permanently or temporarily stored in a storage medium. The non-transitory computer-readable medium is not a medium that stores data for a short time such as a cache and a memory, but a medium that can semi-permanently store data and can be read out by a device. As detailed examples of the non-transitory computer-readable medium, there may be a CD, a DVD, a hard disk, a Blu-ray disc, a USB, a memory card, a ROM, etc.

As described above, exemplary embodiments have been disclosed in the drawings and specification. Although specific terms have been used in this specification to describe the embodiments, these have been used solely for the purpose of explaining the technical spirit of the present disclosure and are not intended to limit the scope of the present disclosure as set forth in the claims. Accordingly, those skilled in the art would understand that various and equivalent modifications can be achieved from the embodiments. Therefore, the technical protective region of the present disclosure should be determined by the scope described in claims.

The maskless exposure system according to an embodiment enables high-resolution and high-precision patterning by detecting minute alignment errors of a substrate through an image processing function and correcting them in real time. Accordingly, the overlay accuracy in an exposure process is improved, whereby the overall process yield and productivity are improved.

Further, in an embodiment, attitude information such as roll, yaw, and pitch of a substrate is automatically measured and reflected in real time in the exposure process, whereby it is possible to minimize errors even in processes requiring precision on the order of several nanometers. This enables increasing exposure precision for substrates having complex three-dimensional structures or irregular shapes.

Further, in an embodiment, by using a maskless exposure method, mask manufacturing and management costs can be reduced, and rapid pattern changes are possible when products are changed, thereby improving production flexibility.

Further, in an embodiment, unlike existing manual or semi-automatic alignment methods, image processing-based automatic position correction minimizes operator intervention and enables a fully automated process flow, thereby significantly improving the efficiency and repeatability of the entire process.

What is claimed is:

1. A maskless exposure system having an image processing function for substrate positioning, the maskless exposure system comprising:
a management information processing device configured to receive and store image data to be exposed;
a controller configured to receive the image data from the management information processing device and convert the image data into an output image;
a stage on which a substrate to be exposed is mounted and configured to move in a direction opposite to an exposure direction and generate encoder signals while moving;
an image capturing unit configured to capture an image of the substrate and transmit the image to the management information processing device;
a trigger generator configured to receive the encoder signals from the stage, accumulate the number of pulses of the received encoder signals, and generate a trigger signal when the accumulated number of pulses corresponds to a position to be exposed;
a DMD control unit configured to receive the output image from the controller and, generate a DMD control signal on the basis of the output image when receiving the trigger signal from the trigger generator;
a light source configured to emit exposure light;
a DMD configured to receive the DMD control signal from the DMD control unit and reflect the light from the light source by adjusting angles of specific micromirrors on the basis of the DMD control signal to expose a desired position on the substrate; and
an optical system configured to refract the light reflected by the DMD to expose a desired position on the substrate to the light,
wherein the management information processing device comprises:
an image processing unit configured to calculate roll (rotation), yaw (later deviation), and pitch (longitudinal tilt) errors of the substrate on the basis of the image received from the image capturing unit; and
an image correcting unit configured to generate a corrected image by correcting the image to be exposed on the basis of the roll (rotation), yaw (later deviation), and pitch (longitudinal tilt) errors of the substrate calculated by the image processing unit.

2. The maskless exposure system of claim 1, wherein the image processing unit extracts reference markers or feature points on the substrate from the image, calculates position errors between actual positions of the extracted feature points and reference positions, calculates roll (rotation), yaw (later deviation), and pitch (longitudinal tilt) information of the substrate on the basis of the position errors, and corrects the position of the substrate on the basis of the calculated roll, yaw, and pitch information.

3. The maskless exposure system of claim 2, wherein the image processing unit corrects the roll, yaw, and pitch of the substrate by correcting and controlling a position and an orientation of the stage supporting the substrate.

4. The maskless exposure system of claim 2, wherein the image processing unit estimates orientation errors of the substrate using relative distances and angles between the reference markers through matrix transformation or the least squares method.

5. The maskless exposure system of claim 2, wherein the image processing unit detects the reference markers after performing pre-processing, which includes at least one of filtering, binarization, edge detection, and corner detection, on the image.

6. The maskless exposure system of claim 2, wherein the reference positions comprise a predefined alignment reference coordinate system based on a layout design of the substrate or a master coordinate system.

7. The maskless exposure system of claim 2, wherein the position errors are determined on the basis of an average value or a weighted average value calculated from a plurality of reference markers on the substrate.

8. The maskless exposure system of claim 2, wherein the image processing unit performs the position correction in a three-dimensional coordinate system when the substrate has a curved or irregular shape.
